(19) United States
(12) Patent Application Publication
(10) Pub. No.: US 2007/0159907 A1
(43) Pub. Date: Jul. 12, 2007

(54) Multi-chip package reducing peak power-up current

(76) Inventor: Pan-Suk Kwak, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/593,495

(22) Filed: Nov. 7, 2006

(30) Foreign Application Priority Data
Jan. 9, 2006 (KR) 2006-02297

(51) Int. Cl. G11C 5/14

(52) U.S. Cl. 365/226

(57) ABSTRACT

A multi-chip package is disclosed comprising a plurality of memory chips, each of the memory chips comprising an internal circuit; and a power level detector for detecting a level of a power supply voltage to initialize the internal circuit, at a power-up. The power level detectors in the respective memory chips are configured to initialize corresponding internal circuits at different points of time.

### BACKGROUND OF THE INVENTION

1. Field of the Invention

Embodiments of the invention relate to a multi-chip package and packaging technique. More particularly, embodiments of the invention relate to a multi-chip package comprising a plurality of memory chips.

This application claims priority under 35 U.S.C § 119 to Korean Patent Application 2006-02297 filed on Jan. 9, 2006, the contents of which are hereby incorporated by reference.

2. Description of Related Art

Multi-chip packages are conventionally used to operationally group a plurality of semiconductor memory chips for use as a storage medium within electronic devices, such as computers. Semiconductor memory chips may be roughly divided between Random Access Memory (RAM) and Read Only Memory (ROM). ROM is commonly provided in the form of non-volatile memory devices capable of retaining stored data even when the power is turned off. ROM devices include programmable ROM (PROM), erasable PROM (EPROM), electrically EPROM (EEPROM), flash memory, etc. In contrast, RAM is implemented in volatile memory devices such as dynamic RAM (DRAM), a static RAM (SRAM), etc.

Each memory chip in a multi-chip package includes a power level detector (PLD) configured to detect a power supply voltage level and to reset or initialize internal circuits such as latches, registers, and the like. Respective power level detectors are configured to reset or initialize internal circuits when a power supply voltage reaches a predetermined voltage level. In this manner, the internal circuits within the respective memory chips may be reset or initialized at the same time.

While this capability is advantageous in some ways, it also tends to increase current consumption (and peak current consumption in particular) during power-up operations. For example, it is assumed that a multi-chip package is equipped with four memory chips. According to this assumption, the multi-chip package will consume about four times as much current upon power-up as is typically required to power-up a single memory chip. This increased current consumption has adverse implications to memory system specifications and related power supply sizing.

### SUMMARY OF THE INVENTION

In one embodiment, the invention provides a multi-chip package comprising; a plurality of memory chips, each of the memory chips comprising an internal circuit, and a power level detector adapted to detect a level of a power supply voltage initializing the internal circuit during a power-up operation, wherein each power level detector in the respective memory chips is differently configured to initialize a corresponding internal circuit at a different activation point during a power supply voltage ramp interval.

In another embodiment, the invention provides a multi-chip package comprising; a plurality of memory chips, each of the memory chips comprising an internal circuit, and a power level detector adapted to detect a level of a power supply voltage initializing the internal circuit during a power-up operation, wherein each power level detector in the respective memory chips is differently configured to initialize a corresponding internal circuit at a different activation point during a power supply voltage ramp interval in response to a different combination of signals indicating a unique bonding option for the corresponding memory chip.

### BRIEF DESCRIPTION OF THE DRAWINGS

FIG. (FIG.) 1 is a block diagram showing a multi-chip package according to an embodiment of the present invention.

FIG. 2 is a table illustrating exemplary voltage levels for bonding option signals useful in the context of embodiment shown in FIG. 1.

FIG. 3 shows a voltage/current consumption profile in the context of initialization signal waveforms for a multi-chip package such as the one illustrated in FIG. 1.

### DESCRIPTION OF EMBODIMENTS

The present invention will now be described in some additional detail with reference to the accompanying drawings in which several embodiments of the invention are shown. This invention may, however, be embodied in many different forms and should not be construed as being limited to only the embodiments set forth herein. Rather, these embodiments are presented as teaching examples. In the drawings, like numbers refer to like or similar elements.

FIG. 1 shows a schematic block diagram of a multi-chip package (“MCP”) according to one embodiment of the invention. MCP 100 comprises a plurality of memory chips 110 through 140. Four (4) memory chips are used in the illustrated example, but those of ordinary skill in the art will recognize that any reasonable number of semiconductor chips, memory related or otherwise, might be used. Memory chips in a multi-chip package can be arranged in many manners. Further, the illustrated example of FIG. 1 shows a vertical arrangement (e.g., an arrangement within a single vertical plane) of memory chips. Here again, this is merely one possible example of the many different chip arrangements that might be used in embodiments of the present invention.

Referring to FIG. 1, first through fourth memory chips 110 through 140, respectively, are assumed to have the same internal circuit configurations; however this need not be the case. For convenience for description, the illustrated example will be described in the context of first memory chip 110 with all the other memory chips being similarly treated. First memory chip 110 includes an internal circuit 111, a power level detector 112, a power pad 10, a first bonding pad 11, and a second bonding pad 12.

Although not shown in FIG. 1, internal circuit 111 may include a circuit adapted to write data to a constituent memory cell array and read data from the cell array in response to externally provided commands. Internal circuit 111 may comprise one or more registers, latches, and flip-flop circuits, such as those conventionally adapted to operate within the context of the memory device read/write operations. Such data registers, data latches, data queues, flip-flop circuits, and similar internal circuits will hereafter be referred to, collectively and/or individually, as “registers” for the sake of brevity. In this context, the term “registers” includes many circuits commonly used to temporarily store data during a read/write operation. Such registers may require reset or initialized upon power-up of MCP 100.

Power level detector 112 is adapted to receive a power supply voltage (e.g., VDD) from power pad 10. Upon power-up, as is well known in the art, power supply voltage VDD increases to a predetermined voltage level over a defined interval of time. This interval of time will be referred to as a “power supply voltage ramp interval”. Power level detector 112 detects the level of the power supply voltage VDD and generates an initialization signal INIT1 adapted to reset the registers in internal circuit 111.

As illustrated in FIG. 1, power level detector 112 is configured to receive signals indicative of a first and a second bonding option (BOP1 and BOP2) through first and second bonding pads 11 and 12, respectively. Power level detector 112 is further configured to decode the first and second bonding option signals BOP1 and BOP2 and then determine an activation point for initialization signal INIT1. For example, power level detector 112 may be configured to adjust an activation point for initialization signal INIT1 using one or more commonly understood delay elements.

In the working example, first and second bonding pads 11 and 12 of first memory chip 110 are commonly connected to a ground pin GND. As a result, the first and second bonding option signals BOP1 and BOP2 of first memory chip 110 are set to ground or a logically “low” levels. Unlike first memory chip 110, first and second bonding pads 21 and 22 of second memory chip 120 are respectively connected to a ground pin GND and a power supply pin VDD. As a result, first and second bonding option signals BOP1 and BOP2 of second memory chip 120 are set to low and high levels, respectively. First and second bonding pads 31 and 32 of third memory chip 130 are respectively connected to a power supply pin VDD and a ground pin GND. As a result, the first and second bonding option signals BOP1 and BOP2 of third memory chip 130 are set to high and low levels, respectively. Finally, first and second bonding pads 41 and 42 of fourth memory chip 140 are commonly connected to a power supply pin VDD. As a result, the first and second bonding option signals BOP1 and BOP2 of fourth memory chip 140 are commonly set to a high level.

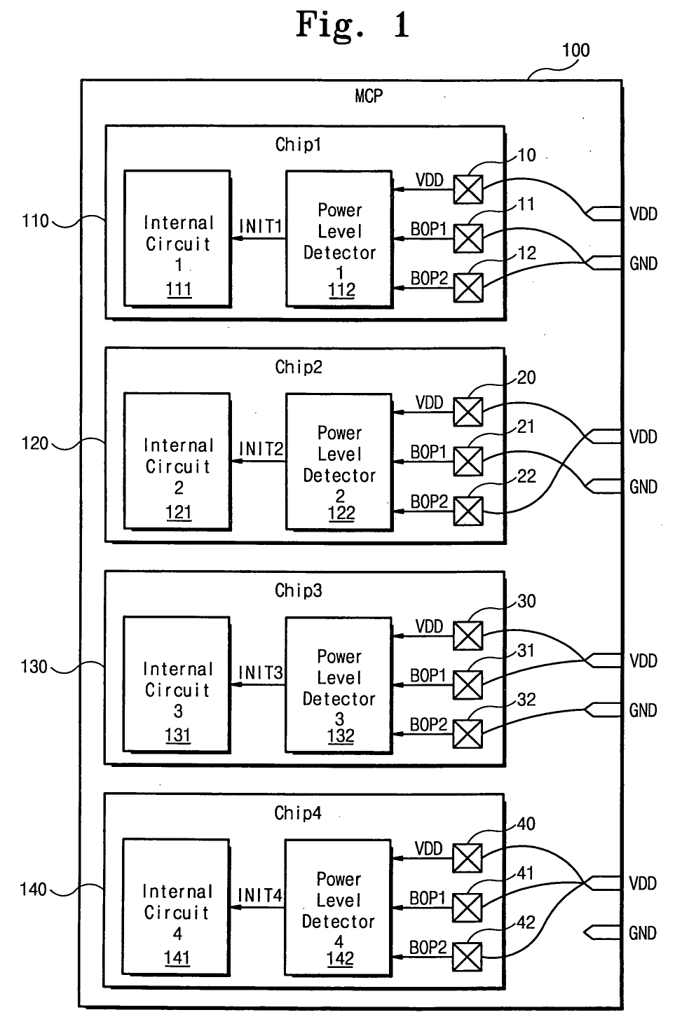

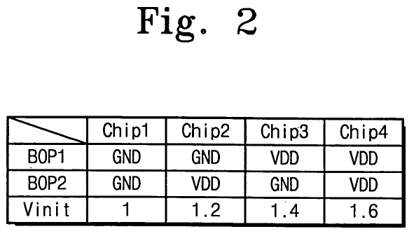

Consistent with this example, FIG. 2 is a table illustrating voltage levels of bonding option signals according to the various bonding options of the multi-chip package illustrated in FIG. 1. Referring collectively to FIGS. 1 and 2, first memory chip 110 generates an initialization voltage (Vinit) of 1 V in response to the first and second bonding option signals BOP1 and BOP2 being set to a low level. Second memory chip 120 generates an initialization voltage Vinit of 1.2 V in response to the first and second bonding option signals BOP1 and BOP2 being set to low and high levels, respectively. Third memory chip 130 generates an initialization voltage Vinit of 1.4 V in response to the first and second bonding option signals BOP1 and BOP2 being set to high and low levels, respectively. Finally, fourth memory chip 140 generates an initialization voltage Vinit of 1.6 V in response to the first and second bonding option signals BOP1 and BOP2 being set to a high level.

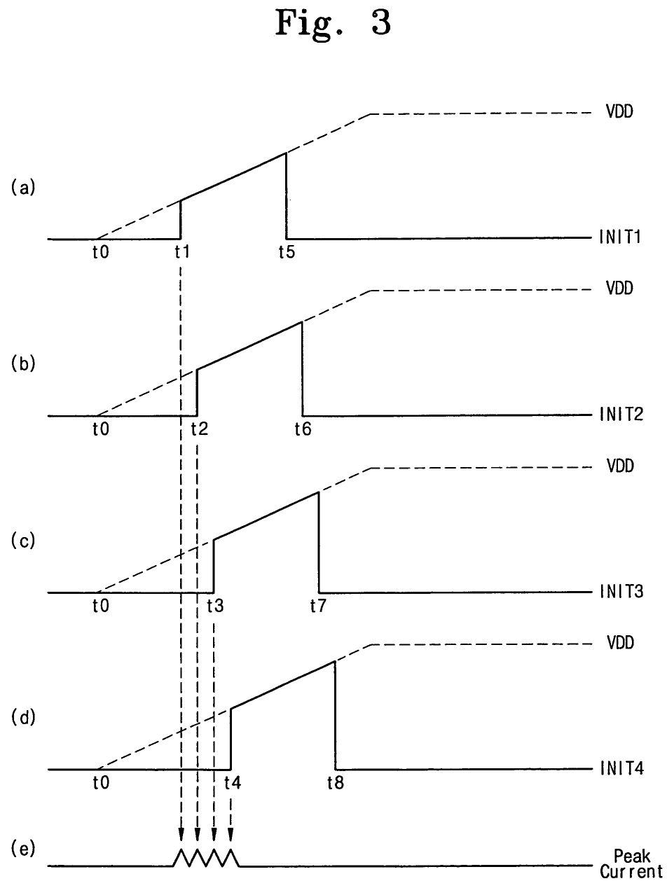

FIG. 3 shows a related collection of current consumption and initialization signal waveforms for the multi-chip package illustrated in FIG. 1 operating under the foregoing assumptions. FIG. 3(a) shows an initialization signal INIT1 for first memory chip 110; FIG. 3(b) an initialization signal INIT2 of a second memory chip 120; FIG. 3(c) an initialization signal INIT3 of a third memory chip 130; and FIG. 3(d) an initialization signal INIT4 of a fourth memory chip 140. FIG. 3(e) shows current consumption for MCP 100 that results from application of initialization signals INIT1 through INIT4.

Referring to FIG. 3(a), a power supply voltage VDD starts to increase at time t0 upon power-up. The first initialization signal INIT1 has a first level (e.g., 1 V) as an initialization voltage at time t1, and follows the power supply voltage VDD from t1 to t5. The first initialization signal INIT1 transitions to a low level at time t5.

Referring to FIG. 3(b), the second initialization signal INIT2 has a second voltage level (e.g., 1.2 V) as an initialization voltage at time t2 and follows the power supply voltage VDD from t2 to t6. The second initialization signal INIT2 transitions to a low level of a ground voltage at time t6. As illustrated in FIG. 3(c), the third initialization signal INIT3 has a third voltage level (e.g., 1.4 V) as an initialization voltage at time t3 and follows the power supply voltage VDD from t3 to t7. The third initialization signal INIT3 transitions to a low level of a ground voltage at time t7. As illustrated in FIG. 3(d), the fourth initialization signal INIT4 has a fourth voltage level (e.g., 1.6 V) as an initialization voltage at time t4 and follows the power supply voltage VDD from t4 to t8. The fourth initialization signal INIT4 transitions to a low level of a ground voltage at time t8.

Referring to FIG. 3(e), peak current consumption for MCP 100 is illustrated in accordance with the foregoing activations of first through fourth initialization signals INIT1-INIT4. Peak current consumption of MCP 100 occurs at each respective initialization signal activation point during the power supply voltage ramp interval. Since the respective activation points do not simultaneously occur, peak current consumption is reduced over conventional multi-chip packages initializing multiple chips at the same time. Naturally, specific activation points may be determined in relation to specific MCP designs and functionality requirements. However, embodiments of the present invention enjoy reduced peak current consumption over analogous multi-chip packages. Reduction of peak power-up current reduces the chance of current stress induced malfunctions in the memory chips. In one embodiment, a MCP may be applied to the provision of a plurality of NAND flash memory chips.

Although the present invention has been described in connection with particular embodiment(s) illustrated in the accompanying drawings, it is not limited thereto. It will be apparent to those skilled in the art that various substitution, modifications and changes may be thereto without departing from the scope of the invention as defined by the following claims.

What is claimed is:

1. A multi-chip package comprising:
a plurality of memory chips, each of the memory chips comprising an internal circuit, and a power level detector adapted to detect a level of a power supply voltage initializing the internal circuit during a power-up operation,
wherein each power level detector in the respective memory chips is differently configured to initialize a corresponding internal circuit at a different activation point during a power supply voltage ramp interval.

2. The multi-chip package of claim 1, wherein each power level detector in the respective memory chips is configured to initialize the corresponding internal circuit at a different activation point using at least one delay element.

3. The multi-chip package of claim 1, wherein each power level detector in the respective memory chips is configured to initialize the corresponding internal circuit at different initialization voltage level.

4. The multi-chip package of claim 1, wherein each of the memory chips further comprises a plurality of bonding pads.

5. The multi-chip package of claim 4, wherein each one of the bonding pads in the plurality of bonding pads is connected in a particular bonding option to a power pin or a ground pin.

6. The multi-chip package of claim 5, wherein each power level detector in the respective memory chips differently determines an activation point during the power supply voltage ramp interval in accordance with a particular bonding option.

7. The multi-chip package of claim 1, wherein the memory chips are a NAND flash memory chip.

8. A multi-chip package comprising:
a plurality of memory chips, each of the memory chips comprising an internal circuit, and a power level detector adapted to detect a level of a power supply voltage initializing the internal circuit during a power-up operation;
wherein each power level detector in the respective memory chips is differently configured to initialize a corresponding internal circuit at a different activation point during a power supply voltage ramp interval in response to a different combination of signals indicating a unique bonding option for the corresponding memory chip.

9. The multi-chip package of claim 8, wherein each unique bonding option corresponds to at least two bonding pads respectively connected to a ground pin or a power pin.
